(19) United States
(12) Patent Application Publication
(10) Pub. No.: US 2014/0124852 A1
(43) Pub. Date: May 8, 2014

(54) SEMICONDUCTOR DEVICE WITH REDUCED MILLER CAPACITANCE AND FABRICATION METHOD THEREOF

(71) Applicant: ANPEC ELECTRONICS CORPORATION, Hsin-Chu (TW)

(72) Inventor: Yung-Fa Lin, Hsinchu City (TW)

(73) Assignee: ANPEC ELECTRONICS CORPORATION, Hsin-Chu (TW)

(21) Appl. No.: 13/719,190

(22) Filed: Dec. 18, 2012

(30) Foreign Application Priority Data
Nov. 8, 2012 (TW) 101141608

(51) Int. Cl. H01L 29/78

(52) U.S. Cl. CPC H01L 29/7813
USPC 257/330

(57) ABSTRACT

A semiconductor transistor device includes an epitaxial layer grown on a semiconductor substrate; an ion well with a junction depth in the epitaxial layer; a gate trench with a depth shallower than the junction depth in the ion well; a recess at the bottom of the gate trench; a gate oxide layer at surface of the gate trench and in the recess to form a protruding tip structure; a gate in the gate trench; and a drain extension region between the gate trench and the epitaxial layer.

### BACKGROUND OF THE INVENTION

1. Field of the Invention

The present invention relates generally to the field of semiconductor technology. More particularly, the present invention relates to a method for fabricating a metal-oxide-semiconductor field-effect transistor (MOSFET) device with reduced Miller capacitance.

2. Description of the Prior Art

As known in the art, the rise of on-resistance of traditional planar power DMOS devices (DMOS) is contributed from the channel region, the accumulation layer and junction field effect transistor (JFET).

In order to reduce the resistance of the above-mentioned area, trench type power devices (UMOS) are proposed. Since JFET region does not exist in a UMOS, the cell size can be reduced and the channel density is increased, thereby resulting in a lower on-resistance, but on the other hand, the UMOS devices has higher gate-to-drain capacitance (Miller capacitance) that affects the switching speed.

### SUMMARY OF THE INVENTION

It is one object of the present invention to provide an improved power semiconductor device and fabrication method thereof in order to reduce Miller capacitance.

According to one embodiment, a power semiconductor device includes a semiconductor substrate having a first conductivity type; an epitaxial layer on the semiconductor substrate; an ion well having a second conductivity type in the epitaxial layer, wherein the ion well has a well junction depth; a gate trench in the ion well; a recessed trench at the bottom of the gate trench; a gate oxide layer on interior surface of the gate trench and fills the recessed trench to thereby form a tip extrusion structure; a gate within the gate trench; and a drain extension region having the first conductivity type between the gate trench and the epitaxial layer and is adjacent to the tip extrusion structure.

According to another embodiment, a power semiconductor device includes a semiconductor substrate having a first conductivity type; an epitaxial layer on the semiconductor substrate; an ion well having a second conductivity type in the epitaxial layer, wherein the ion well has a well junction depth; a gate trench in the ion well; a gate oxide layer on interior surface of the gate trench; a gate within the gate trench; and a tip extension doping region having the first conductivity type between the gate trench and the epitaxial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic, cross-sectional diagrams illustrating a method for fabricating a semiconductor transistor device in accordance with one embodiment of the invention.

FIG. 9 illustrates another embodiment wherein the sacrificial oxide layer is first etched into a spacer, then the tip ion implantation process is carried out.

FIGS. 10-15 are schematic, cross-sectional diagrams illustrating a method for fabricating a semiconductor transistor device in accordance with another embodiment of the invention.

### DETAILED DESCRIPTION

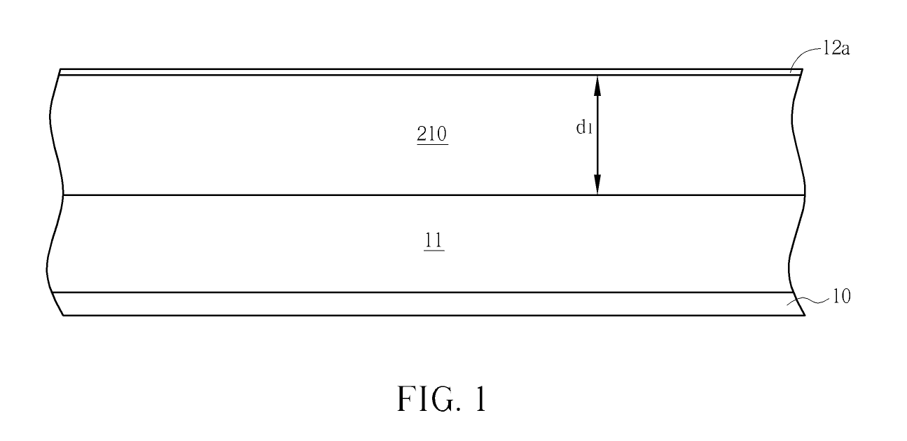

FIGS. 1-8 are schematic, cross-sectional diagrams illustrating a method for fabricating a semiconductor transistor device in accordance with one embodiment of the invention. As shown in FIG. 1, a semiconductor substrate 10, such as an N type heavily doped silicon substrate, is provided. The semiconductor substrate 10 may act as a drain of the semiconductor transistor device. Subsequently, an epitaxial process is performed to form an epitaxial layer 11 such as an N type epitaxial silicon layer on the semiconductor substrate 10. A pad oxide layer 12a may be formed on the epitaxial layer 11. An ion implantation process is then carried out to form an ion well 210 such as a P well in the epitaxial layer 11. The ion well 210 has a well junction depth d1.

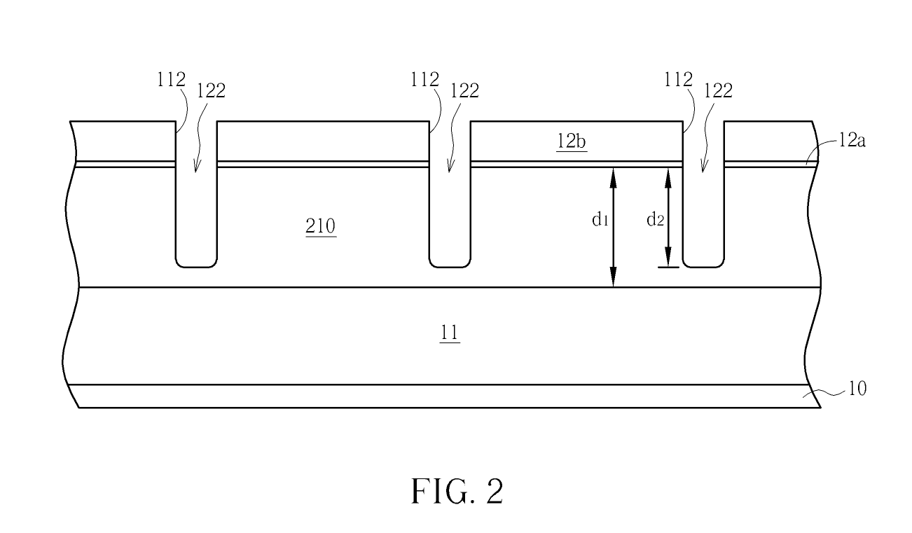

As shown in FIG. 2, a hard mask layer 12b such as a silicon nitride layer is deposited on the epitaxial layer 11. A lithographic process and an etching process are performed to form openings 112 in the hard mask layer 12b. Subsequently, a dry etching process is performed to etch the epitaxial layer 11 through the openings 112 to a predetermined depth d2 within the ion well 210, thereby forming gate trenches 122. The trench depth d2 of the gate trenches 122 is shallower than well junction depth d1.

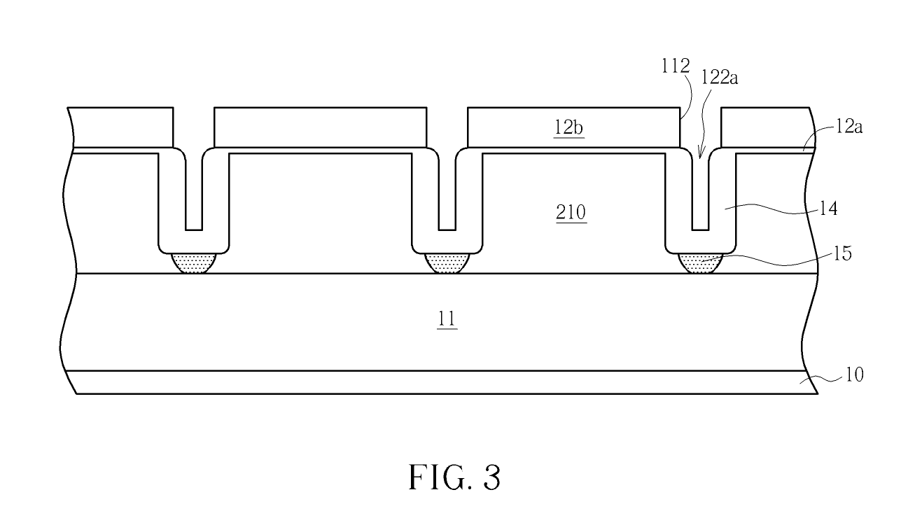

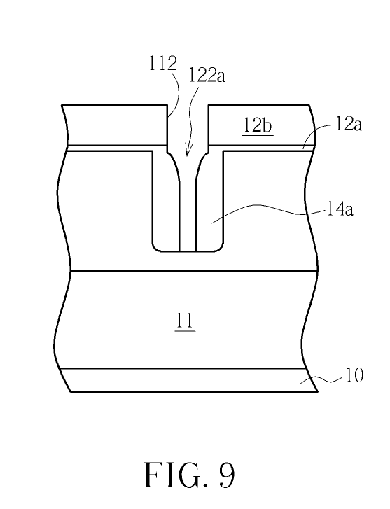

As shown in FIG. 3, the interior surfaces of the gate trenches 122 are oxidized to form a sacrificial oxide layer 14 within each of the gate trenches 122. In another embodiment, the sacrificial oxide layer 14 may be formed by using deposition and etching processes, which form a sidewall spacer instead. It is noteworthy that the sacrificial oxide layer 14 conformally covers the interior surface of each gate trench 122 and does not completely fill the gate trench 122, thereby leaving a seam 122a in each gate trench 122. Subsequently, a tip ion implantation process is performed to implant N type dopants through the seam 122a of each gate trench 122 into the ion well 210, thereby forming a tip extension doping region 15. According to another embodiment, as shown in FIG. 9, after forming the sacrificial oxide layer 14, an etching process is performed to etch the sacrificial oxide layer 14 into a sidewall spacer 14a, then the aforesaid tip ion implantation process is performed.

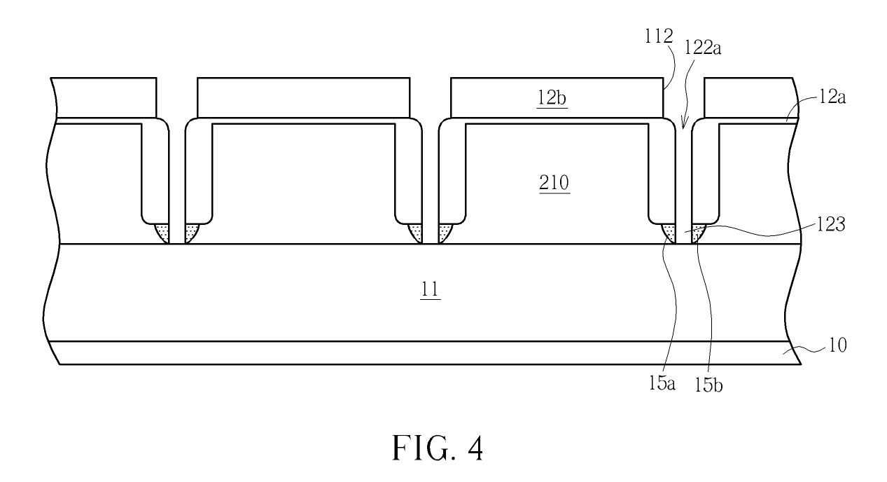

As shown in FIG. 4, another dry etching process is performed using the sacrificial oxide layer 14 as an etch hard mask to etch the epitaxial layer 11 through the seam 122a to the depth of about the well junction depth d1, thereby revealing a portion of the epitaxial layer 11 and forming a recessed trench 123 under each gate trench 122 that substantially splits the tip extension doping region 15 into a left portion and a right portion, which function as drain extension regions 15a and 15b. It is noteworthy that the dimension of the recessed trench 123 can be controlled or determined by the thickness of the sacrificial oxide layer 14.

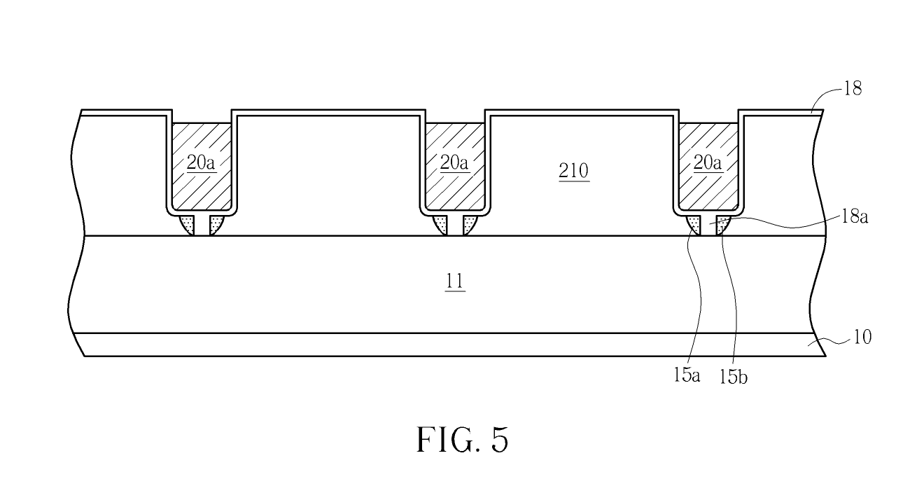

As shown in FIG. 5, the pad oxide layer 12a, the hard mask layer 12b and the sacrificial oxide layer 14 are removed to expose the surface of the ion well 210 and the interior surfaces of the gate trenches 122. Subsequently, a thermal oxidization process is performed to form a gate oxide layer 18 that fills the recessed trench 123 to form a tip extrusion structure 18a directly under the gate trench 122. A chemical vapor deposition (CVD) process is then performed to deposit a polysilicon layer that fills the gate trenches 122. The polysilicon layer is etched back to form gate 20a within each gate trench 122.

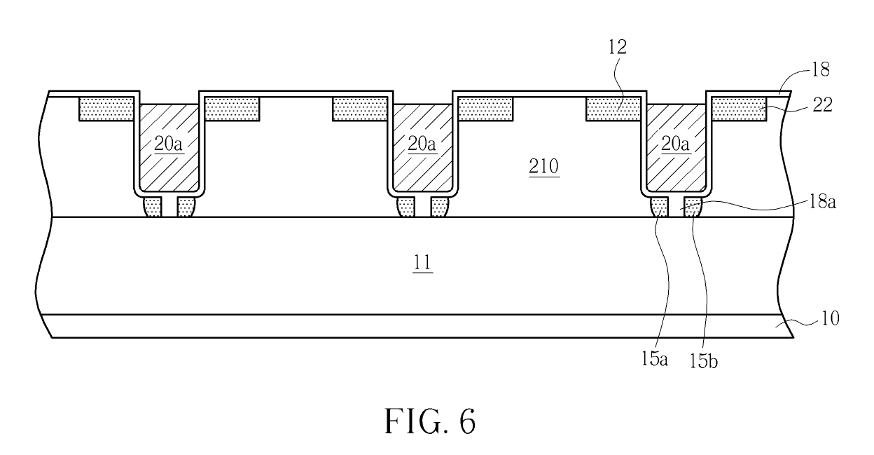

As shown in FIG. 6, a patterned photoresist layer (not shown) is then formed by using conventional lithographic process. The patterned photoresist layer defines the source region. An ion implantation process is carried out to implant dopants such as N type dopants into the source region defined by the patterned photoresist layer, thereby forming source doping region 22 within the ion well 210. Thereafter, the patterned photoresist layer is removed. A thermal drive-in process may be performed to activate the implanted dopants.

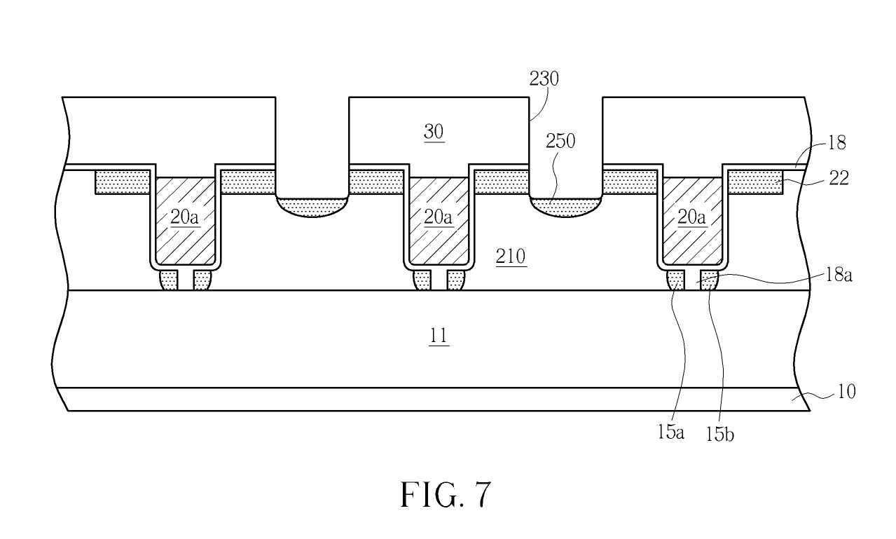

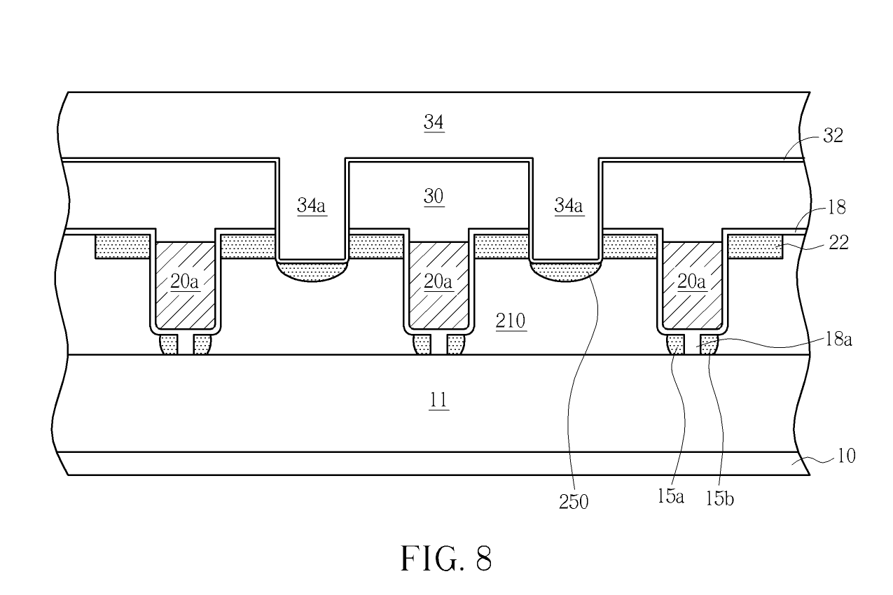

As shown in FIGS. 7-8, contact holes are formed and metalized. To form the metalized contact holes, an inter-layer dielectric (ILD) layer 30 is first deposited. Then contact holes 230 are formed in ILD layer 30. Thereafter, contact doping region 250 is formed at the bottom of each of the contact holes 230. Barrier layer 32 and metal layer 34 are deposited to fill the contact holes 230, thereby forming the contact elements 34a.

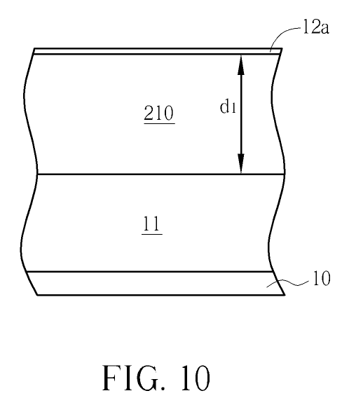

FIGS. 10-15 are schematic, cross-sectional diagrams illustrating a method for fabricating a semiconductor transistor device in accordance with another embodiment of the invention. As shown in FIG. 10, a semiconductor substrate 10, such as an N type heavily doped silicon substrate, is provided. The semiconductor substrate 10 may act as a drain of the semiconductor transistor device. Subsequently, an epitaxial process is performed to form an epitaxial layer 11 such as an N type epitaxial silicon layer on the semiconductor substrate 10. A pad oxide layer 12a may be formed on the epitaxial layer 11. An ion implantation process is then carried out to form an ion well 210 such as a P well in the epitaxial layer 11. The ion well 210 has a well junction depth d1.

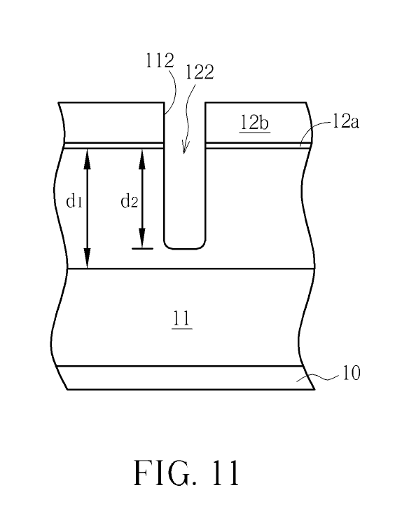

As shown in FIG. 11, a hard mask layer 12b such as a silicon nitride layer is deposited on the epitaxial layer 11. A lithographic process and an etching process are performed to form openings 112 in the hard mask layer 12b. Subsequently, a dry etching process is performed to etch the epitaxial layer 11 through the openings 112 to a predetermined depth d2 within the ion well 210, thereby forming gate trenches 122. The trench depth d2 of the gate trenches 122 is shallower than well junction depth d1.

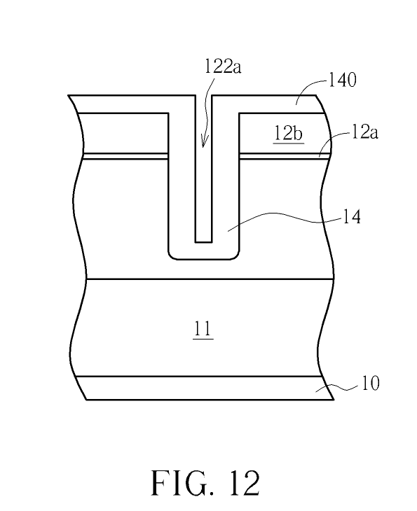

As shown in FIG. 12, a conformal oxide layer 140 is deposited on the interior surfaces of the gate trenches 122 and the surface of the hard mask layer 12b. The oxide layer 140 conformally covers the interior surface of each gate trench 122 and does not completely fill the gate trench 122, thereby leaving a seam 122a in each gate trench 122.

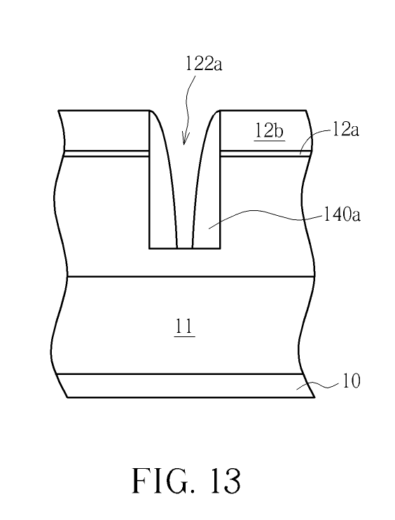

As shown in FIG. 13, an etching process is performed to etch the conformal oxide layer 140 into a spacer 140a. The bottom of the gate trench 122 is partially exposed.

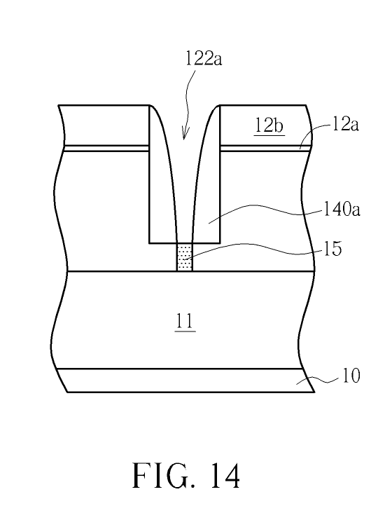

As shown in FIG. 14, subsequently, a tip ion implantation process is performed to implant N type dopants through the seam 122a of each gate trench 122 into the ion well 210, thereby forming a tip extension doping region 15. According to this embodiment, the tip extension doping region 15 is not etched or split.

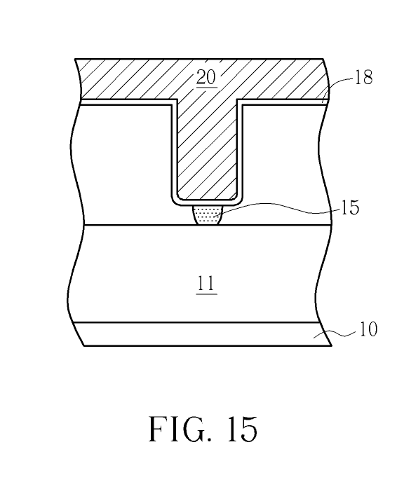

As shown in FIG. 15, the pad oxide layer 12a, the hard mask layer 12b and the spacer 140a are removed to expose the surface of the ion well 210 and the interior surfaces of the gate trenches 122. Subsequently, a thermal oxidization process is performed to form a gate oxide layer 18. A CVD process is then performed to deposit a polysilicon layer 20 that fills the gate trenches 122.

Subsequently, similar to the steps depicted in FIGS. 6-8, the polysilicon layer 20 is etched back to form gate 20a in each gate trench 122. A lithographic process is performed to form a patterned photoresist layer that defines a source region. An ion implantation process is carried out to implant dopants such as N type dopants into the source region defined by the patterned photoresist layer, thereby forming source doping region 22 within the ion well 210. Thereafter, contact holes are formed and metalized. To form the metalized contact holes, an ILD layer 30 is first deposited. Then contact holes 230 are formed in ILD layer 30. Thereafter, contact doping region 250 is formed at the bottom of each of the contact holes 230. Barrier layer 32 and metal layer 34 are deposited to fill the contact holes 230, thereby forming the contact elements 34a.

Those skilled in the art will readily observe that numerous modifications and alterations of the device and method may be made while retaining the teachings of the invention. Accordingly, the above disclosure should be construed as limited only by the metes and bounds of the appended claims.

1. A power semiconductor device, comprising:
a semiconductor substrate having a first conductivity type;
an epitaxial layer on the semiconductor substrate;
an ion well having a second conductivity type in the epitaxial layer, wherein the ion well has a well junction depth;
a gate trench in the ion well;
a recessed trench at the bottom of the gate trench;
a gate oxide layer on interior surface of the gate trench and fills the recessed trench to thereby form a tip extrusion structure;
a gate within the gate trench; and
a drain extension region having the first conductivity type between the gate trench and the epitaxial layer and is adjacent to the tip extrusion structure.

2. The power semiconductor device according to claim 1 further comprising a source doping region disposed at a surface of the ion well and being adjacent to the gate trench.

3. The power semiconductor device according to claim 2 wherein the source doping region has the first conductivity type.

4. The power semiconductor device according to claim 1 wherein the first conductivity type is N type and the second conductivity type is P type.

5. The power semiconductor device according to claim 1 wherein the epitaxial layer has the first conductivity type.

6. The power semiconductor device according to claim 1 wherein the gate trench has a trench depth that is shallower than the well junction depth.

7-12. (canceled)
